(19) United States
(12) Patent Application Publication
(10) Pub. No.: US 2026/0082752 A1
(43) Pub. Date: Mar. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: Jin-Su BYUN, Yongin-si (KR); YEONGWOO KWON, Yongin-si (KR); Si Kwang KIM, Yongin-si (KR); Yang-Ho JUNG, Yongin-si (KR)

(21) Appl. No.: 19/266,048

(22) Filed: Jul. 10, 2025

(30) Foreign Application Priority Data
Sep. 13, 2024 (KR) 10-2024-0126137

(51) Int. Cl. H10H 29/80; H10H 29/39; H10H 29/41; H10K 59/123; H10K 59/124; H10K 59/80; H10K 102/10

(52) U.S. Cl. CPC H10H 29/8323; H10H 29/39; H10H 29/41; H10H 29/882; H10K 59/123; H10K 59/124; H10K 59/80517; H10K 59/877; H10K 2102/101

(57) ABSTRACT

A display device includes: a substrate; a transistor above the substrate; a first insulating layer above the substrate; a second insulating layer on the first insulating layer; a first pixel electrode on the first insulating layer; a scattering layer on the first pixel electrode and is in contact with the second insulating layer; a second pixel electrode on the scattering layer and overlaps the first pixel electrode in a plan view; a light emitting layer on the second pixel electrode; and a common electrode on the light emitting layer, wherein at least one of the first pixel electrode or the second pixel electrode is electrically connected to the transistor.

### CROSS-REFERENCE TO RELATED APPLICATION

The present application claims priority to and the benefit of Korean Patent Application No. 10-2024-0126137, filed on Sep. 13, 2024, at the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

A display device may include a light emitting display device including light emitting elements corresponding to pixels. A light emitting display device may display an image by controlling brightness of each light emitting element included in the light emitting display device. Unlike a light receiving display device such as a liquid crystal display device, the light emitting display device does not require a light source such as a backlight, and thus it may have a reduced thickness and weight. In addition, quality of the image of the light emitting display device may be relatively improved by characteristics such as high luminance, contrast ratio, color reproduction, or reaction speed.

To provide high-quality images, the light emitting display device is applied to various electronic devices such as a mobile device (e.g., a smartphone, a tablet, or a laptop computer), a monitor, and a television, and is also used in a display device for a vehicle or the like.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device including a light emitting element.

Aspects of some embodiments include a display device with relatively improved light out-coupling efficiency (or relatively improved light extraction efficiency).

Aspects of some embodiments include a display device capable of preventing or reducing display defects in which dark spots are visually recognized.

A display device according to some embodiments includes: a substrate, a transistor that is above the substrate, a first insulating layer that is above the substrate, a second insulating layer that is on the first insulating layer, a first pixel electrode that is on the first insulating layer, a scattering layer that is on the first pixel electrode and is in contact with the second insulating layer, a second pixel electrode that is on the scattering layer and overlaps the first pixel electrode on a plane, a light emitting layer that is on the second pixel electrode, and a common electrode that is on the light emitting layer. According to some embodiments, at least one of the first pixel electrode or the second pixel electrode is electrically connected to the transistor.

According to some embodiments, the first insulating layer may include a contact hole, and the first pixel electrode may overlap the contact hole on a plane.

According to some embodiments, the second pixel electrode may overlap the contact hole on a plane.

According to some embodiments, the second pixel electrode may not overlap the contact hole on a plane.

According to some embodiments, the second pixel electrode may be in contact with at least a portion of a side surface of the scattering layer.

According to some embodiments, the second insulating layer may be in contact with at least a portion of a side surface of the scattering layer.

According to some embodiments, the second insulating layer may be in contact with all of the first pixel electrode, the scattering layer, and the second pixel electrode.

According to some embodiments, the second pixel electrode in its entirety may overlap the first pixel electrode on a plane.

According to some embodiments, the first pixel electrode may include a first transparent conductive oxide layer including transparent conductive oxide and a first metal layer including a metallic material, and the second pixel electrode may include a second transparent conductive oxide layer including transparent conductive oxide.

According to some embodiments, the scattering layer may include a photoresist resin and a plurality of scatterers within the photoresist resin.

A display device according to some embodiments includes: a substrate, a transistor that is above the substrate, a first insulating layer that is above the substrate and includes a contact hole, a second insulating layer that is on the first insulating layer, a first pixel electrode that is electrically connected to the transistor, a scattering layer that is on the first pixel electrode and is in contact with the first insulating layer; a second pixel electrode that is on the scattering layer and partially overlaps the first pixel electrode; a light emitting layer that is on the second pixel electrode; and a common electrode that is on the light emitting layer. According to some embodiments, only one of the first pixel electrode and the second pixel electrode overlaps the contact hole on a plane, and at least one end portion of the second pixel electrode is in contact with both the first insulating layer and the second insulating layer.

According to some embodiments, the second pixel electrode may cover the upper and side surfaces of the scattering layer in their entireties.

According to some embodiments, the first pixel electrode may overlap the contact hole on a plane, and the second pixel electrode may not overlap the contact hole on a plane.

According to some embodiments, the first pixel electrode may not overlap the contact hole on a plane, and the second pixel electrode may overlap the contact hole on a plane.

According to some embodiments, the first pixel electrode may be separated from the second pixel electrode.

According to some embodiments, the second pixel electrode may cover the first pixel electrode in its entirety.

According to some embodiments, the scattering layer may cover the first pixel electrode between the first pixel electrode and the second pixel electrode in its entirety.

A display device according to some embodiments includes: a substrate; a transistor that is above the substrate; a first insulating layer that is above the substrate; a second insulating layer that is on the first insulating layer; a first pixel electrode that is on the first insulating layer; a scattering layer that is on the first pixel electrode and is in contact with both the first insulating layer and the second insulating layer; a second pixel electrode that is on the scattering layer and overlaps the first pixel electrode on a plane; a light emitting layer that is on the second pixel electrode; and a common electrode that is on the light emitting layer.

According to some embodiments, the first insulating layer may include a contact hole, and at least one of the first pixel electrode or the second pixel electrode may overlap the contact hole.

According to some embodiments, the second insulating layer may overlap all of the first pixel electrode, the scattering layer, and the second pixel electrode on a plane.

An electronic device according to some embodiments includes: a display device which includes a substrate, a transistor that is above the substrate, a first insulating layer that is above the substrate, a second insulating layer that is on the first insulating layer, a first pixel electrode that is on the first insulating layer, a scattering layer that is on the first pixel electrode and is in contact with the second insulating layer, a second pixel electrode that is on the scattering layer and overlaps the first pixel electrode on a plane a light emitting layer that is on the second pixel electrode, and a common electrode that is on the light emitting layer. According to some embodiments, at least one of the first pixel electrode or the second pixel electrode is electrically connected to the transistor.

According to some embodiments, the scattering layer is in contact with the first insulating layer.

An electronic device according to some embodiments includes: a display device which includes a substrate, a transistor that is above the substrate, a first insulating layer that is above the substrate and includes a contact hole, a second insulating layer that is on the first insulating layer, a first pixel electrode that is electrically connected to the transistor, a scattering layer that is on the first pixel electrode and is in contact with the first insulating layer, a second pixel electrode that is on the scattering layer and partially overlaps the first pixel electrode, a light emitting layer that is on the second pixel electrode, and a common electrode that is on the light emitting layer. According to some embodiments, only one of the first pixel electrode and the second pixel electrode overlaps the contact hole on a plane, and at least one end portion of the second pixel electrode is in contact with both the first insulating layer and the second insulating layer.

According to some embodiments, light out-coupling efficiency may be relatively improved to relatively improve luminance characteristics of a display device.

In addition, the embodiments may reduce damage to a light emitting element, and may prevent or reduce display defects such as dark spots.

### BRIEF DESCRIPTION OF THE DRAWINGS

FIG. 1 is a schematic perspective view of a display device according to some embodiments.

FIG. 2 is a schematic cross-sectional view illustrating a portion of a display area of a display device according to some embodiments.

FIGS. 3 to 6 are schematic plan views illustrating a positional relationship between a pixel electrode and a scattering layer of a display device according to some embodiments.

FIG. 7 is a photograph of a pixel electrode and a scattering layer of a display device according to a comparative example.

FIG. 8 is a photograph of a light emitting area of a display device according to a comparative example.

FIG. 9 is a photograph of a pixel electrode and a scattering layer of a display device according to some embodiments.

FIG. 10 is a photograph of a light emitting area of a display device according to some embodiments.

FIGS. 11 to 14 are schematic cross-sectional views illustrating a method for manufacturing a display device according to some embodiments.

FIG. 15 is a schematic cross-sectional view illustrating a portion of a display area of a display device according to some embodiments.

FIG. 16 is a schematic plan view illustrating a positional relationship between a pixel electrode and a scattering layer of a display device according to some embodiments.

FIG. 17 is a schematic cross-sectional view illustrating a portion of a display area of a display device according to some embodiments.

FIG. 18 is a schematic plan view illustrating a positional relationship between a pixel electrode and a scattering layer of a display device according to some embodiments.

FIG. 19 and FIG. 20 are schematic cross-sectional views illustrating a portion of a display area of a display device according to some embodiments.

FIG. 21 is a block diagram of an electronic device according to some embodiments.

FIG. 22 is schematic diagram of electronic devices according to some embodiments.

### DETAILED DESCRIPTION

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, each element's size and thickness are arbitrarily illustrated for ease of description, but the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means located on or below a referenced part, and does not necessarily mean located on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

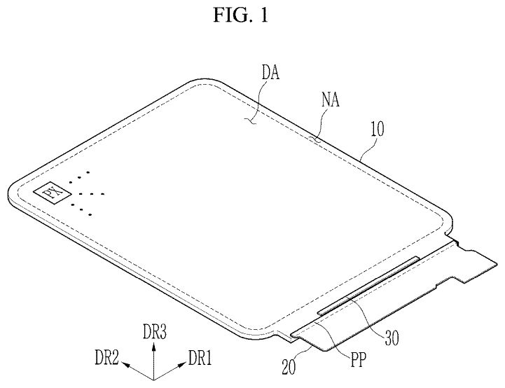

A display device according to some embodiments will now be described with reference to FIG. 1.

FIG. 1 is a schematic perspective view of the display device according to some embodiments.

Referring to FIG. 1, the display device may be used to display an image on an electronic device such as a mobile phone, a smartphone, a tablet, a laptop computer, a monitor, a multimedia player, or a game machine. The display device may include a driving device including a display panel 10, a flexible printed circuit board 20 and an integrated circuit chip 30 bonded to the display panel 10, and the like.

The display panel 10 may include a display area DA corresponding to a screen at which images are displayed, and a non-display area NA in which circuits and signal lines for generating and transferring various signals applied to the display area DA are located, and at which images are not displayed. The non-display area NA may surround (e.g., in a periphery or outside a footprint of) the display area DA. In FIG. 1, inner and outer sides of a dotted-line quadrangle may each correspond to the display area DA and the non-display area NA.

Pixels PX arranged in a matrix may be included in the display area DA of the display panel 10. Although FIG. 1 illustrates a single pixel PX for convenience of illustration, as a person having ordinary skill in the art would appreciate, the display panel 10 may include any suitable number of pixels PX according to the design and size of the display panel 10.

Additionally, signal lines such as a gate line, a data line, and a driving voltage line may be located in the display area DA. The gate line may extend in a first direction DR1, and the data line and the driving voltage line may extend in a second direction DR2. Signal lines such as the gate line, the data line, and the driving voltage line may be connected to each pixel PX so that each pixel PX receives a gate signal (also referred to as a scan signal), a data voltage, a driving voltage, and the like from the signal lines. Each pixel PX may include a light emitting element LE and a pixel circuit portion connected thereto. The pixel circuit portion may generate a driving current based on signals applied through the signal lines such as the gate line and the data line to apply current to the light emitting element LE. The pixel circuit portion may include at least one transistor and at least one capacitor connected to the signal lines.

A touch sensor for sensing a user's contact and non-contact touch may be located in the display area DA. Although FIG. 1 shows the display area DA in a quadrangular shape, the display area DA may have various shapes other than the quadrangular shape such as a polygonal shape, a circular shape, and an elliptical shape.

A pad portion PP including pads configured to receive signals from the outside of the display panel 10 may be located in the non-display area NA of the display panel 10. The pad portion PP may be arranged to extend in the first direction DR1 along one edge of the display panel 10. The flexible printed circuit board 20 may be bonded to the pad portion PP, and pads of the flexible printed circuit board 20 may be electrically connected to the pads of the pad portion PP.

A driving unit (or a driving device) that generates and processes various signals for driving the display panel 10 may be located in the non-display area NA of the display panel 10. The driving device may include a data driver that applies the data voltage to data lines, a gate driver that applies the gate signal to gate lines, and a signal controller that controls the data driver and the gate driver. The pixels PX may receive the data voltage according to the gate signal generated by the gate driver. The gate driver may be integrated into the display panel 10, and may be located at least on one side of the display area DA. The data driver and the signal controller may be provided as the integrated circuit chip (also referred to as a driving IC chip or a driving IC), and the integrated circuit chip 30 may be mounted in the non-display area NA of the display panel 10. The integrated circuit chip 30 may be mounted on the flexible printed circuit board 20 or the like to be electrically connected to the display panel 10.

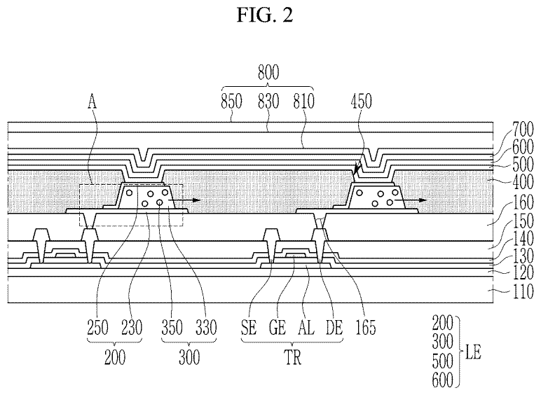

A detailed cross-sectional structure of the display device according to some embodiments will now be described with reference to FIG. 2 together with FIG. 1.

FIG. 2 is a schematic cross-sectional view illustrating a portion of the display area of the display device according to some embodiments.

Referring to FIG. 2, a buffer layer 120 may be located on a substrate 110. The buffer layer 120 may relatively improve a characteristic of a semiconductor layer by blocking impurities from the substrate 110 when the semiconductor layer is formed, and may relieve stress on the semiconductor layer by planarizing a surface of the substrate 110. The buffer layer 120 may be an inorganic insulating layer that may include an inorganic insulating material such as silicon nitride (SiNₓ), silicon oxide (SiOₓ), or silicon oxynitride (SiOₓN_{y}), and may have a single-layer structure or a multi-layer structure.

A semiconductor layer AL of the transistor TR may be located above the substrate 110. The semiconductor layer AL may include a first conductive area, a second conductive area, and a channel area located between the first conductive area and the second conductive area. The semiconductor layer AL may include any one of amorphous silicon, polycrystalline silicon, and an oxide semiconductor. For example, the semiconductor layer AL may include low-temperature polycrystalline silicon (LTPS), or an oxide semiconductor material including at least one of zinc (Zn), indium (In), gallium (Ga), or tin (Sn). For example, the semiconductor layer AL may include indium gallium zinc oxide (IGZO).

A gate insulating layer 130 may be located on the semiconductor layer AL. The gate insulating layer 130 may include an inorganic insulating material such as silicon nitride, silicon oxide, or silicon oxynitride. The gate insulating layer 130 may have a single-layer structure or a multi-layer structure.

A gate conductive layer that may include a gate electrode GE of the transistor TR or the like may be located on the gate insulating layer 130. The gate conductive layer may include molybdenum (Mo), aluminum (Al), copper (Cu), titanium (Ti), or the like, and may have a single-layer structure or a multi-layer structure.

A first interlayer insulating layer 140 may be located on the gate conductive layer. The first interlayer insulating layer 140 may include an inorganic insulating material such as silicon nitride, silicon oxide, or silicon oxynitride. The first interlayer insulating layer 140 may have a single-layer structure or a multi-layer structure. An additional gate conductive layer may be located on the first interlayer insulating layer 140.

A second interlayer insulating layer 150 may be located on the first interlayer insulating layer 140. The second interlayer insulating layer 150 may include an inorganic insulating material such as silicon nitride, silicon oxide, or silicon oxynitride. The second interlayer insulating layer 150 may include an organic insulating material such as a general-purpose polymer (e.g., poly(methyl methacrylate) or polystyrene), a polymer derivative having a phenol-based group, an acryl-based polymer, an imide-based polymer (e.g., polyimide), or a siloxane-based polymer. The second interlayer insulating layer 150 may have a single-layer structure or a multi-layer structure.

A data conductive layer that may include a first electrode SE, a second electrode DE, and the like may be located on the second interlayer insulating layer 150. The first electrode SE and the second electrode DE may be each connected to the first conductive area and the second conductive area of the semiconductor layer AL through contact holes formed in the insulating layers 130, 140, and 150. One of the first electrode SE and the second electrode DE may be a source electrode, and the other may be a drain electrode.

The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like, and may have a single-layer structure or a multi-layer structure. For example, the data conductive layer may include a lower layer including a refractory metal such as molybdenum, chromium, tantalum, or titanium, an intermediate layer including a low-resistivity metal such as aluminum, copper, or silver, and an upper layer including a refractory metal. For example, the data conductive layer may have a triple-layer structure such as titanium (Ti)/aluminum (Al)/titanium (Ti).

The semiconductor layer AL, the gate insulating layer 130, the gate electrode GE, the first electrode SE, and the second electrode DE may together form the transistor TR. For example, the transistor TR including the semiconductor layer AL, the gate insulating layer 130, the gate electrode GE, the first electrode SE, and the second electrode DE may be located above the substrate 110. For example, the transistor TR may be located on the buffer layer 120 located on the substrate 110.

A first insulating layer 160 may be located on the data conductive layer. The first insulating layer 160 located on the data conductive layer may be provided as a planarization layer. For example, the first insulating layer 160 provided as the planarization layer may be located on the transistor TR including the semiconductor layer AL, the gate electrode GE, the first electrode SE, and the second electrode DE. The first insulating layer 160 may be located on the first interlayer insulating layer 140.

The first insulating layer 160 may include an organic insulating material such as a general-purpose polymer (e.g., poly(methyl methacrylate) or polystyrene), a polymer derivative having a phenol-based group, an acryl-based polymer, an imide-based polymer (e.g., polyimide), or a siloxane-based polymer.

The first insulating layer 160 may include a contact hole 165. The contact hole 165 may refer to a hole formed from an upper surface of the first insulating layer 160 to an upper surface of the second interlayer insulating layer 150.

According to some embodiments, the light emitting element LE may be located on the first insulating layer 160. For example, the light emitting element LE may be located on the first insulating layer 160, and may be electrically connected to the transistor TR.

The light emitting element LE may include a pixel electrode 200. For example, the pixel electrode 200 may be an anode of the light emitting element LE. The pixel electrode 200 may include a first pixel electrode 230 and a second pixel electrode 250.

The pixel electrode 200 may overlap the contact hole 165 of the first insulating layer 160. At least one of the first pixel electrode 230 or the second pixel electrode 250 may overlap the contact hole 165 of the first insulating layer 160. The pixel electrode 200 may be electrically connected to the transistor TR through the contact hole 165 of the first insulating layer 160. At least one of the first pixel electrode 230 or the second pixel electrode 250 may be electrically connected to the transistor TR through the contact hole 165 of the first insulating layer 160.

The first pixel electrode 230 may be located on the first insulating layer 160. The first pixel electrode 230 may be located on the first insulating layer 160 to overlap the second pixel electrode 250 on a plane. The second pixel electrode 250 may be located on the first pixel electrode 230. The second pixel electrode 250 may be located on the first pixel electrode 230 to overlap the first pixel electrode 230 on a plane. For example, the second pixel electrode 250 in its entirety may overlap the first pixel electrode 230 on a plane. The first pixel electrode 230 may be in contact with the upper surface of the first insulating layer 160.

The first pixel electrode 230 may include a transparent conductive material. The first pixel electrode 230 may include transparent conductive oxide as the transparent conductive material. For example, the first pixel electrode 230 may include the transparent conductive oxide such as indium tin oxide (ITO) or indium zinc oxide (IZO). The first pixel electrode 230 may include the transparent conductive material such as graphene, carbon nanotube (CNT), or Ag nanowire.

Additionally, the first pixel electrode 230 may further include a semi-transmissive conductive material. The first pixel electrode 230 may include a metallic material as the semi-transmissive conductive material. For example, the first pixel electrode 230 may include the metallic material such as lithium (Li), calcium (Ca), aluminum (Al), silver (Ag), magnesium (Mg), gold (Au), or an alloy thereof.

Accordingly, the first pixel electrode 230 may reflect light refracted or scattered in the direction of the substrate toward the light emitting element LE. Therefore, an amount of light emitted in a frontal direction may increase.

The first pixel electrode 230 may include a first transparent conductive oxide layer including the transparent conductive material described above and a first metal layer including the semi-transmissive conductive material described above. The first pixel electrode 230 may be a multi-layer structure including the first transparent conductive oxide layer and the first metal layer. For example, it may have a double-layer structure such as ITO/silver (Ag), IZO/silver (Ag), ITO/aluminum (Al), or IZO/aluminum (Al), and may have a triple-layer structure such as ITO/silver (Ag)/ITO, IZO/silver (Ag)/IZO, ITO/aluminum (Al)/ITO, or IZO/aluminum (Al)/IZO. The first pixel electrode 230 may include the first metal layer having low resistivity so that electrical conductivity of the first pixel electrode 230 may be relatively improved.

The second pixel electrode 250 may include a transparent conductive material. The second pixel electrode 250 may include transparent conductive oxide as the transparent conductive material. For example, the second pixel electrode 250 may include the transparent conductive oxide such as ITO or IZO. The second pixel electrode 250 may include the transparent conductive material such as graphene, CNT, or silver (Ag) nanowire.

The second pixel electrode 250 may include a second transparent conductive oxide layer including the transparent conductive material described above. For example, the second pixel electrode 250 may have a single-layer structure including the second transparent conductive oxide layer. Accordingly, transmittance of light passing through a scattering layer 300 to be described later may be relatively improved. Therefore, visibility of the display area DA may be relatively improved.

According to some embodiments, the second pixel electrode 250 may further include a semi-transmissive conductive material. The second pixel electrode 250 may include a metallic material as the semi-transmissive conductive material. For example, the second pixel electrode 250 may further include the metallic material such as lithium (Li), calcium (Ca), aluminum (Al), silver (Ag), magnesium (Mg), gold (Au), or an alloy thereof. The first pixel electrode 230 may have a multi-layer structure including the second transparent conductive oxide layer and the semi-transmissive conductive material. For example, the first pixel electrode 230 may have a triple-layer structure such as ITO/silver (Ag)/ITO or ITO/aluminum (Al)/ITO.

The light emitting element LE according to some embodiments may further include the scattering layer 300 located between the first pixel electrode 230 and the second pixel electrode 250. The scattering layer 300 may be in contact with an upper surface of the first pixel electrode 230. The scattering layer 300 may be in contact with the first pixel electrode 230 and the second pixel electrode 250 between the first pixel electrode 230 and the second pixel electrode 250. The scattering layer 300 may overlap the first pixel electrode 230 and the second pixel electrode 250 on a plane.

The first pixel electrode 230 may be in contact with a lower surface of the scattering layer 300. According to some embodiments, the entire lower surface of the scattering layer 300 may be in contact with the first pixel electrode 230. The second pixel electrode 250 may be in contact with at least a portion of a side surface of the scattering layer 300. The second pixel electrode 250 may be in contact with at least a portion of an upper surface of the scattering layer 300. The second pixel electrode 250 may be in contact with the entire upper surface of the scattering layer 300.

Here, the upper surface may be substantially parallel to an upper surface of the substrate 110, and the substantial paralleling may mean that an average slope of the upper surface of the scattering layer 300 is substantially the same as an average slope of the upper surface of the substrate 110. Additionally, the substantial paralleling may mean that a difference between the average slope of the upper surface of the scattering layer 300 and the average slope of the upper surface of the substrate 110 is within about 10°, about 5°, or about 3°.

Here, the lower surface may be substantially parallel to the upper surface of the substrate 110, and the substantial paralleling may mean that an average slope of the lower surface of the scattering layer 300 is substantially the same as the average slope of the upper surface of the substrate 110. Additionally, the substantial paralleling may mean that a difference between the average slope of the lower surface of the scattering layer 300 and the average slope of the upper surface of the substrate 110 is within about 10°, about 5° or about 3°.

Here, the side surface may mean a surface having a constant slope with respect to the upper surface of the scattering layer 300, and the constant slope may mean no substantial paralleling. The side surface may mean a surface whose internal angle with respect to the upper surface of the scattering layer 300 is about 10° to about 160°, about 20° to about 150°, or about 30° to about 140°.

The scattering layer 300 may include a photoresist resin 330 and a plurality of scatterers 350 located inside the photoresist resin 330. The scatterers 350 may be distributed inside photoresist resin 330. The scatterers 350 may be evenly distributed over the entire area of the photoresist resin 330 inside the photoresist resin 330.

The photoresist resin 330 may include a positive photoresist resin or a negative photoresist resin. For example, the photoresist resin 330 may include a novolac-based resin or the like as the positive photoresist resin. For example, the photoresist resin 330 may include an epoxy-based resin or the like as the negative photoresist resin.

The scatterers 350 may include a material capable of scattering light. For example, the scatterers 350 may include titanium dioxide (TiO₂), silicon dioxide (SiO₂), barium sulfate (BaSO₄), zinc oxide (ZnO), aluminum oxide (Al₂O₃), calcium carbonate (CaCO₃), or the like. The scatterers 350 may be evenly distributed inside the photoresist resin 330 to scatter light so that a light path is changed. For example, a portion of light generated from a light emitting layer of the light emitting element LE may be extinguished by a plurality of reflections during a resonance process between the pixel electrode 200 and a common electrode 600. The scatterers 350 included in the scattering layer 300 may change the light path by scattering light resonating between the pixel electrode 200 and the common electrode 600. Accordingly, an amount of light emitted that is extinguished may be reduced, and an amount of light emitted in a frontal direction may be increased. Therefore, white angular difference (WAD) according to a change of a side surface angle may be relatively improved, and light out-coupling efficiency toward the frontal direction may be relatively improved.

A second insulating layer 400 may be located on the first insulating layer 160. The second insulating layer 400 may include a black pixel defining layer (BPDL) including a light blocking material. For example, the second insulating layer 400 may include a light blocking material such as a resin or a paste including carbon black, carbon nanotube, a black dye, or the like, a metal particle (e.g., nickel, aluminum, molybdenum, or an alloy thereof), or a metal oxide particle (e.g., chromium nitride). The second insulating layer 400 may include the light blocking material to reduce reflection of external light by metal structures located below the second insulating layer 400.

The second insulating layer 400 located on the first insulating layer 160 may also be referred to as a pixel defining layer. The second insulating layer 400 provided as the pixel defining layer may include an organic insulating material such as a general-purpose polymer (e.g., poly(methyl methacrylate) or polystyrene), a polymer derivative having a phenol-based group, an acryl-based polymer, an imide-based polymer, or a siloxane-based polymer.

The second insulating layer 400 may be located at the same layer or level as that of the scattering layer 300. For example, both the scattering layer 300 and the second insulating layer 400 may be located between the first insulating layer 160 and an intermediate layer 500 to be described later.

According to some embodiments, the scattering layer 300 may be in contact with the second insulating layer 400. For example, the second insulating layer 400 may be in contact with at least a portion of a side surface of the scattering layer 300. The second insulating layer 400 may be in contact with at least a portion of an upper surface of the scattering layer 300. That is, at least a portion of the side surface of the scattering layer 300 and at least a portion of the upper surface of the scattering layer 300 may be in contact with the second insulating layer 400. Here, the upper surface and the side surface of the scattering layer 300 may have the same meaning as described above. For example, the upper surface may mean a surface substantially parallel to the upper surface of the substrate 110, and the side surface may mean a surface having a constant slope with respect to the upper surface of the scattering layer 300.

The second pixel electrode 250 may expose at least a portion of the side surface of the scattering layer 300 to the second insulating layer 400 without covering at least a portion of the side surface of the scattering layer 300. The second pixel electrode 250 may not cover at least a portion of the upper surface of the scattering layer 300, and at least a portion of the upper surface of the scattering layer 300 may be in contact with the second insulating layer 400. In other words, at least a portion of the side surface of the scattering layer 300 and at least a portion of the upper surface of the scattering layer 300 may be in contact with the second insulating layer 400 through a portion of the scattering layer 300 that is not covered by the second pixel electrode 250. The second pixel electrode 250 may partially expose the scattering layer 300 to the second insulating layer 400, so that a gas generated in the scattering layer 300 (e.g., a gas generated during a step such as a curing step in a process of forming the scattering layer 300) is emitted in the direction (e.g., an arrow direction of FIG. 2) of the second insulating layer 400 contacting the scattering layer 300.

The second insulating layer 400 may be in contact with all of the first pixel electrode 230, the second pixel electrode 250, and the scattering layer 300. The second insulating layer 400 may be in contact with at least a portion of an upper surface of the first pixel electrode 230 and at least a portion of an upper surface of the second pixel electrode 250. For example, the second insulating layer 400 may cover at least a portion of the upper surface of the first pixel electrode 230 and at least a portion of the upper surface of the second pixel electrode 250.

The second insulating layer 400 may have a light emitting opening 450 that overlaps at least a portion of the second pixel electrode 250. The light emitting opening 450 may also overlap the first pixel electrode 230 and the scattering layer 300. For example, the light emitting opening 450 may overlap central portions of the first pixel electrode 230, the second pixel electrode 250, and the scattering layer 300, and may not overlap edge portions of the first pixel electrode 230, the second pixel electrode 250, and the scattering layer 300. Therefore, a planar size of the light emitting opening 450 may be smaller than the planar sizes of the first pixel electrode 230, the second pixel electrode 250, and the scattering layer 300. The light emitting opening 450 may correspond to a light emitting area of each pixel PX described with reference to FIG. 1 on a plane.

The intermediate layer 500 may be located on the pixel electrode 200 and the second insulating layer 400. The intermediate layer 500 may include a light emitting layer and a functional layer.

The light emitting layer may be a layer in which electro-optical conversion is performed through combination of an electron and a hole, and may include at least one of an organic material or an inorganic material that emits light of a color (e.g., a set or predetermined color). The light emitting layer may include a portion located on the pixel electrode 200, and particularly, the light emitting layer may be located on the second pixel electrode 250. The light emitting layer may include a portion located within the light emitting opening 450 of the second insulating layer 400. The light emitting layer may be located within the light emitting opening 450 of the second insulating layer 400, and may overlap at least one of the first pixel electrode 230 or the second pixel electrode 250 on a plane. The light emitting layer may also include a portion located on the second insulating layer 400.

The light emitting layer may include an organic light emitting material or an inorganic light emitting material.

The functional layer may include at least one of a hole injection layer, a hole transport layer, an electron transport layer, or an electron injection layer. The functional layer may include a first functional layer located between the pixel electrode 200 and the light emitting layer, and a second functional layer located between the light emitting layer and the common electrode 600 to be described later. The first functional layer may be located on the second pixel electrode 250.

The first functional layer may include at least one of the hole injection layer or the hole transport layer. The second functional layer may include at least one of the electron transport layer or the electron injection layer. The functional layer may be arranged across the entire display area DA described with reference to FIG. 1. The functional layer may be located within the light emitting opening 450 of the second insulating layer 400. The functional layer may also include a portion located outside the light emitting opening 450 of the second insulating layer 400.

The common electrode 600 may be located on the intermediate layer 500. The common electrode 600 may be located throughout the display area DA described with reference to FIG. 1.

The common electrode 600 may include a low-work function metal or a metal alloy such as calcium (Ca), barium (Ba), magnesium (Mg), aluminum (Al), or silver (Ag). For example, the common electrode 600 may have light transmittance by forming a thin layer of the low-work function metal or metal alloy. According to some embodiments, the common electrode 600 may include a transparent conductive oxide such as ITO or IZO.

The common electrode 600 may form the light emitting element LE that may be a light emitting diode together with the pixel electrode 200, the scattering layer 300, and the intermediate layer 500. For example, the light emitting element LE may include the pixel electrode 200 including the first pixel electrode 230 and the second pixel electrode 250, the scattering layer 300, the intermediate layer 500 including the light emitting layer and the functional layer, and the common electrode 600. The pixel electrode 200 may be an anode of the light emitting element LE, and the common electrode 600 may be a cathode of the light emitting element LE.

A capping layer 700 may be located on the common electrode 600. The capping layer 700 may relatively improve light efficiency by adjusting a refractive index. The capping layer 700 may be arranged to entirely cover the common electrode 600. The capping layer 700 may include at least one of an organic insulating material or an inorganic insulating material. The capping layer 700 may be omitted.

An encapsulation layer 800 may be located on the capping layer 700. The encapsulation layer 800 may seal the light emitting element LE to prevent or reduce contaminants such as moisture or oxygen from penetrating from the outside. The encapsulation layer 800 may be a thin-film encapsulation layer including one or more inorganic layers 810 and 850 and one or more organic layers 830.

A touch sensor layer including touch electrodes may be located on the encapsulation layer 800. The touch electrodes may have a mesh shape having an opening overlapping the light emitting element LE. An anti-reflection layer for reducing reflection of external light may be further located on the touch sensor layer.

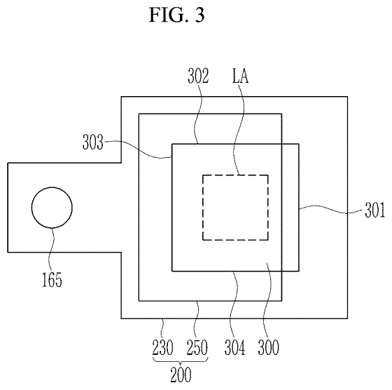

A detailed planar structure of the display device according to some embodiments will now be described with reference to FIGS. 3, 4, 5, and 6 together with FIG. 1 and FIG. 2.

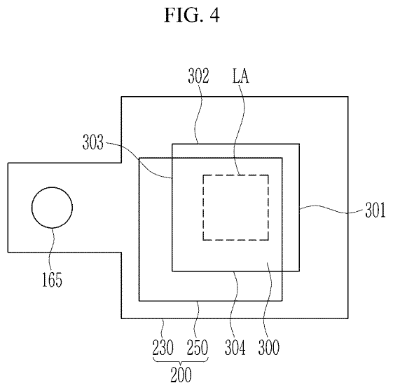

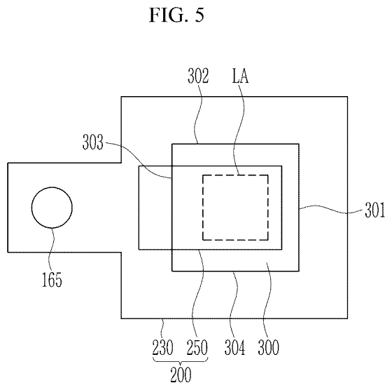

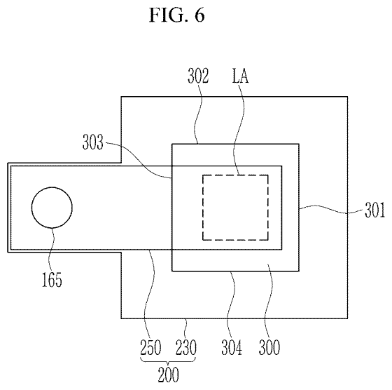

FIG. 3, FIG. 4, FIG. 5, and FIG. 6 are schematic plan views illustrating a positional relationship between the pixel electrode 200 and the scattering layer 300 of the display device according to some embodiments, and are schematic plan views illustrating an area A of FIG. 2.

Referring to FIGS. 1, 2, and 3, the first pixel electrode 230, the second pixel electrode 250, and the scattering layer 300 may overlap a light emitting area LA. As described above, the light emitting opening 450 of the second insulating layer 400 may define the light emitting area LA. The light emitting area LA may mean an area in which light of each pixel PX is emitted.

The first pixel electrode 230 may overlap the contact hole 165 of the first insulating layer 160 on a plane. The first pixel electrode 230 may overlap the contact hole 165 to be electrically connected to the transistor TR through the contact hole 165.

The second pixel electrode 250 may not overlap the contact hole 165 on a plane. The second pixel electrode 250 may overlap the first pixel electrode 230 on a plane, and may not overlap the contact hole 165 on a plane. The second pixel electrode 250 may entirely overlap the first pixel electrode 230 on a plane. An area of the second pixel electrode 250 on a plane may be smaller than that of the first pixel electrode 230 on a plane.

The entire scattering layer 300 in its entirety may be located on the first pixel electrode 230 while overlapping the first pixel electrode 230 on a plane.

In a plan view, the scattering layer 300 may have a planar shape such as a polygonal shape, a circular shape, or an elliptical shape, and the second pixel electrode 250 may not overlap at least some edges of the scattering layer 300 on a plane.

Specifically, the scattering layer 300 according to some embodiments may include a plurality of different edges facing in four directions of top, bottom, left, and right on a plane. According to some embodiments, the second pixel electrode 250 may not overlap at least some of the plurality of different edges of the scattering layer 300 on a plane. That is, the second pixel electrode 250 may only overlap at least some of the plurality of different edges of the scattering layer 300 on a plane.

Specifically, referring to FIGS. 3 to 6, when the scattering layer 300 has a quadrangular planar shape, for example, the scattering layer 300 may have a schematic quadrangular shape having a first edge 301, a second edge 302, a third edge 303, and a fourth edge 304 that face four different directions on a plane and are connected to each other in sequence. The second pixel electrode 250 may not overlap at least one of the first edge 301, the second edge 302, the third edge 303, or the fourth edge 304 of the scattering layer 300.

Referring to FIG. 3, the second pixel electrode 250 may not overlap the first edge 301 of the scattering layer 300 on a plane. In this case, the second pixel electrode 250 may not overlap a portion of at least one of the second edge 302 or the fourth edge 304 adjacent to the first edge 301 of the scattering layer 300 on a plane.

Referring to FIG. 4, the second pixel electrode 250 may not overlap two adjacent edges (for example, the first edge 301 and the second edge 302) of the scattering layer 300 on a plane. In this case, the second pixel electrode 250 may not overlap a portion of at least one of the third edge 303 or the fourth edge 304 of the scattering layer 300 on a plane.

Referring to FIG. 5, the second pixel electrode 250 may not overlap three adjacent edges (for example, the first edge 301, the second edge 302, and the fourth edge 304) of the scattering layer 300 on a plane. In this case, the second pixel electrode 250 may not overlap a portion of the third edge 303 of the scattering layer 300 on a plane.

Because the second pixel electrode 250 does not cover at least some of the edges of the scattering layer 300, at least a portion of a cross-sectional side surface of the scattering layer 300 may be exposed to the second insulating layer 400 so that the scattering layer 300 is in contact with the second insulating layer 400. Accordingly, a gas that may be generated in the scattering layer 300 may be emitted to the second insulating layer 400 rather than to the intermediate layer 500 including the light emitting layer. Therefore, the gas may be isolated in the scattering layer 300 so that instances of the gas damaging the pixel electrode 200, the intermediate layer 500 including the light emitting layer, and the like, may be prevented or reduced. Thus, it may be possible to prevent or reduce a display defect of the display device by preventing or reducing dark spots that may be caused by the damage.

As shown in FIGS. 3 to 5, the first pixel electrode 230 according to some embodiments may overlap the contact hole 165 of the first insulating layer 160, and may be electrically connected to the transistor TR through the contact hole 165. Alternatively, referring to FIG. 6, the first pixel electrode 230 according to some embodiments may extend toward the contact hole 165 of the first insulating layer 160 to overlap the contact hole 165. That is, referring to FIG. 6, both the first pixel electrode 230 and the second pixel electrode 250 may overlap the contact hole 165 of the first insulating layer 160 on a plane. The first pixel electrode 230 and the second pixel electrode 250 may be sequentially stacked on the contact hole 165. One end portion of the second pixel electrode 250 may extend into the contact hole 165.

In FIG. 6, the second pixel electrode 250 is shown as partially covering only one edge of the scattering layer 300, but the second pixel electrode 250 may overlap the contact hole 165, and may overlap two edges or three edges of the scattering layer 300 on a plane, as shown in FIG. 3, FIG. 4, and FIG. 5.

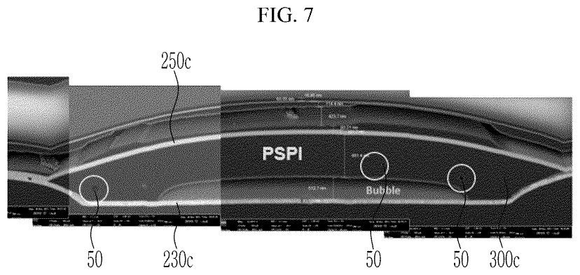

Referring to FIGS. 7 to 10 together with the above-described drawings, an effect according to a structure of the display device according to some embodiments will now be described.

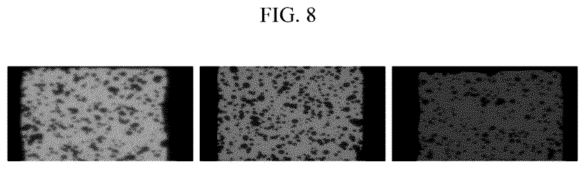

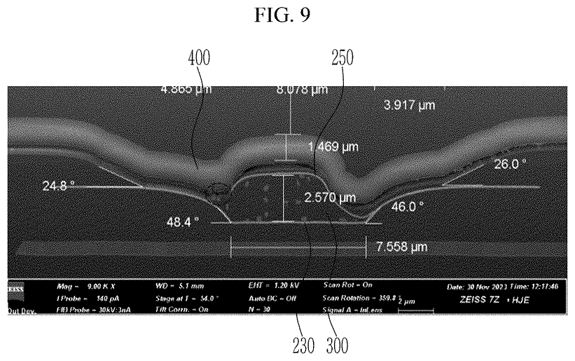

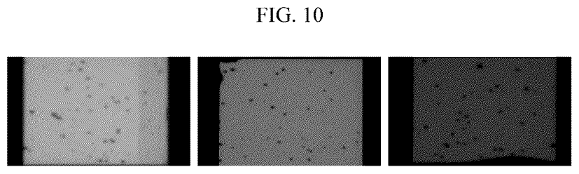

FIG. 7 is a photograph of a pixel electrode and a scattering layer of a display device according to a comparative example. FIG. 8 is a photograph of a light emitting area of the display device according to a comparative example. FIG. 9 is a photograph of a pixel electrode and a scattering layer of the display device according to some embodiments. FIG. 10 is a photograph of a light emitting area of the display device according to some embodiments.

Referring to FIG. 7, the scattering layer 300c of the display device according to the comparative example is isolated or sealed between a first pixel electrode 230c and a second pixel electrode 250c. Accordingly, it may be confirmed that a gas generated inside the scattering layer 300c (for example, a gas generated during a step such as a curing step in a forming process of the scattering layer 300c) is not emitted to the outside of the scattering layer 300c and a void 50 is formed due to the gas. Light may be scattered due to a difference in refractive index at a position where the void 50 within the scattering layer 300c is formed, resulting in a dark spot defect. Additionally, the gas may not be emitted to the outside of the scattering layer 300c, which may damage the first pixel electrode 230c, the second pixel electrode 250c, and the like. Referring to FIG. 8, it may be confirmed that a dark spot defect occurs in a light emitting area. It may be confirmed that the dark spot defect is caused by the void inside the scattering layer 300c.

In contrast, referring to FIG. 9 which shows the embodiments, the scattering layer 300 may be in contact with the second insulating layer 400 while the scattering layer 300 is located between the first pixel electrode 230 and the second pixel electrode 250. For example, a gas generated inside the scattering layer 300 may be in contact with the second insulating layer 400 at a circled portion of FIG. 9 to be emitted to the outside through the second insulating layer 400. Accordingly, the void due to the gas or the like of the comparative example may not be formed inside the scattering layer 300. In addition, damage to the second pixel electrode 250 and the intermediate layer 500 including the light emitting layer due to the gas or the like generated inside the scattering layer 300 may be prevented or reduced. Therefore, occurrence of a dark spot may be prevented or reduced by preventing or reducing a difference in refractive index due to a void or the like inside the scattering layer 300, and damage to the light emitting element LE due to an emission of the gas may be suppressed. Cross-referring FIG. 7 and FIG. 9, it may be confirmed that the gas is easily emitted in a case in which the scattering layer 300 according to some embodiments is exposed to the second insulating layer 400 to be in contact with the second insulating layer 400 compared with a case in which the scattering layer 300c according to the comparative example is isolated by the first pixel electrode 230c and the second pixel electrode 250c even if the gas is generated inside the scattering layer 300 so that there is no void inside the scattering layer 300.

Referring to FIG. 10, it may be confirmed that the number of dark spots is reduced in the light emitting area of the display device according to some embodiments. Cross-referring to FIG. 8 and FIG. 10, it may be confirmed that the dark spot defect in the light emitting area is reduced in a case in which the scattering layer 300 according to some embodiments is exposed to the second insulating layer 400 to be in contact with the second insulating layer 400 compared with a case in which the scattering layer 300c according to the comparative example is isolated by the first pixel electrode 230c and the second pixel electrode 250c.

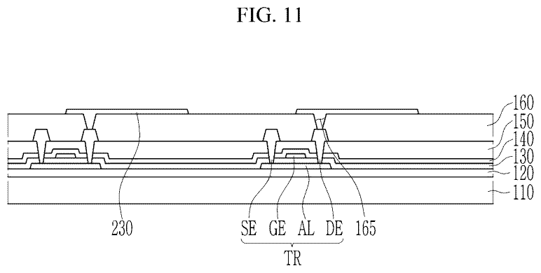

A method for manufacturing the display device according to some embodiments will now be described with reference to FIGS. 11 to 14 together with the above-described drawings.

FIGS. 11 to 14 are schematic cross-sectional views for describing the method for manufacturing the display device according to some embodiments. FIGS. 11 to 14 are schematic cross-sectional views for describing a method for manufacturing the pixel electrode and the scattering layer of the display device according to some embodiments.

First, referring to FIG. 11, the buffer layer 120 may be formed on the substrate 110, and the transistor TR may be formed on the buffer layer 120. For example, the buffer layer 120 may be formed on the substrate 110, and a semiconductor material layer may be formed on the buffer layer 120 and then may be patterned to form the semiconductor layer AL. Next, the gate insulating layer 130 may be formed on the semiconductor layer AL. A conductive material layer may be formed on the gate insulating layer 130 and then may be patterned to form a gate conductive layer that may include the gate electrode GE of the transistor TR. The first interlayer insulating layer 140 may be formed on the gate conductive layer. A conductive material layer may be formed on the first interlayer insulating layer 140 and then may be patterned to form the data conductive layer that may include the first electrode SE and the second electrode DE.

The second interlayer insulating layer 150 may be formed on the first electrode SE and the second electrode DE. The first insulating layer 160 may be formed on the second interlayer insulating layer 150. The first insulating layer 160 may also be referred to as the planarization layer. The contact hole 165 that overlaps at least one of the first electrode SE or the second electrode DE may be formed on the first insulating layer 160 that may be provided as the planarization layer. The light emitting element LE that may be electrically connected to the transistor TR may be formed on the first insulating layer 160.

A conductive material layer may be formed on the first insulating layer 160 and then may be patterned to form the first pixel electrode 230 of the light emitting element LE. The first pixel electrode 230 may be electrically connected to the transistor TR through the contact hole 165 formed in the first insulating layer 160. The first pixel electrode 230 may be formed by forming a first pixel conductive layer and then patterning the first pixel conductive layer.

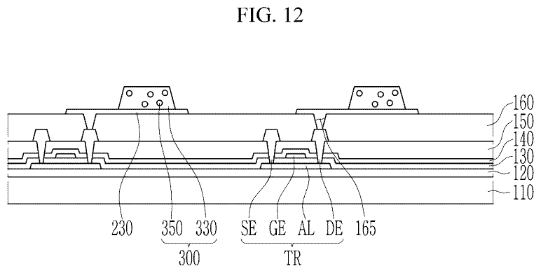

Referring to FIG. 12, the scattering layer 300 may be formed on the first pixel electrode 230. The photoresist resin 330 including the scatterers 350 may be applied on the first pixel electrode 230, and may be patterned using a photo process to form the scattering layer 300. The scattering layer 300 may be formed directly on the first pixel electrode 230. For example, the scattering layer 300 may be formed to contact an upper surface of the first pixel electrode 230.

The photoresist resin 330 may include a positive photoresist resin or a negative photoresist resin. For example, the photoresist resin 330 may be the positive photoresist resin including a novolac-based resin or the like. For example, the photoresist resin 330 may be the negative photoresist resin including an epoxy-based resin or the like.

The scatterers 350 may be located inside the photoresist resin 330. The scatterers 350 may be evenly distributed inside the photoresist resin 330. For example, the scatterers 350 may include titanium dioxide (TiO₂), silicon dioxide (SiO₂), barium sulfate (BaSO₄), zinc oxide (ZnO), aluminum oxide (Al₂O₃), calcium carbonate (CaCO₃), or the like.

While forming the first pixel electrode 230 and then forming the scattering layer 300 has been described, it is also possible to form the first pixel electrode 230 by forming a first pixel conductive layer, forming the scattering layer 300, and then patterning the first pixel conductive layer.

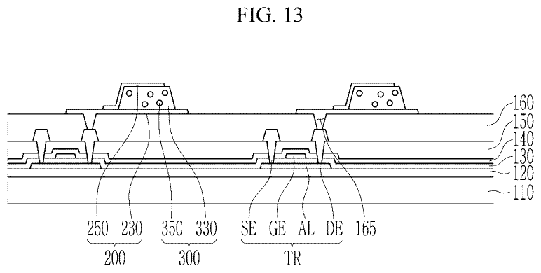

Referring to FIG. 13, the second pixel electrode 250 may be formed on the first pixel electrode 230 and the scattering layer 300. The second pixel electrode 250 may be formed to be in contact with at least a portion of a side surface of the scattering layer 300. The second pixel electrode 250 may be formed not to be in contact with at least a portion of the side surface of the scattering layer 300. The second pixel electrode 250 may be formed to be in contact with at least a portion of an upper surface of the scattering layer 300. The second pixel electrode 250 may be formed to be in contact with the entire upper surface of the scattering layer 300. The second pixel electrode 250 may be formed not to be in contact with at least a portion of the upper surface of the scattering layer 300.

After a second pixel conductive layer is formed on the first pixel electrode 230 and the scattering layer 300 to entirely cover the scattering layer 300, the second pixel conductive layer may be patterned to form the second pixel electrode 250. The patterning may be done by etching the second pixel conductive layer so that the second pixel conductive layer and at least a portion of the side surface of the scattering layer 300 do not contact each other. The patterning may be done by etching the second pixel conductive layer so that the second pixel conductive layer and at least a portion of the upper surface of the scattering layer 300 do not contact each other.

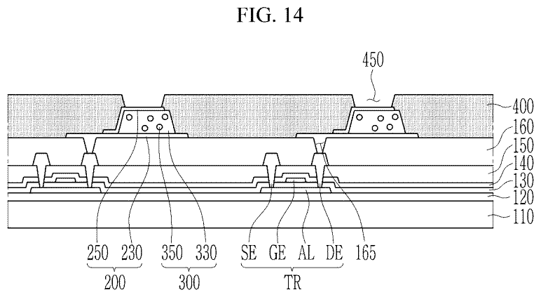

Referring to FIG. 14, the second insulating layer 400 may be formed on the first pixel electrode 230, the second pixel electrode 250, and the scattering layer 300. For example, an organic material layer may be coated on the first pixel electrode 230, the second pixel electrode 250, the scattering layer 300, and the first insulating layer 160, and then may be patterned to form the second insulating layer 400. At least a portion of an upper surface of the second pixel electrode 250 may be exposed from the second insulating layer 400 by the patterning.

The second insulating layer 400 may be formed to be in contact with all of the first pixel electrode 230, the second pixel electrode 250, and the scattering layer 300. Accordingly, a gas that may be generated in a photo process of the scattering layer 300 may be discharged through the second insulating layer 400. Accordingly, the gas may be located inside the scattering layer 300, preventing or reducing damage to the pixel electrode or the like due to the gas or the defect such as dark spots due to voids caused by the gas. The second insulating layer 400 may be provided as a pixel defining layer. The second insulating layer 400 may include a black pixel defining layer.

The intermediate layer including the light emitting layer and the functional layer may be formed on the second pixel electrode 250 and the second insulating layer 400. The light emitting layer may be deposited using a fine metal mask (FMM). The functional layer may be entirely deposited using an open mask. The functional layer may include two or more functional layers.

For example, the first functional layer, the light emitting layer, and the second functional layer may be sequentially formed. The first functional layer and the second functional layer may be entirely deposited using an open mask. Accordingly, the first functional layer and the second functional layer may be formed across the display area in its entirety. The light emitting layer may be deposited using the FMM. The light emitting layer may be widely formed considering a margin of the deposition process, so that a portion of the light emitting layer is formed on the second insulating layer 400.

The common electrode may be formed on the intermediate layer. The capping layer and the encapsulation layer may be formed on the common electrode. The encapsulation layer may be formed to include one or more inorganic layers and one or more organic layers. For example, a first inorganic layer may be formed on the capping layer, an organic layer may be formed on the first inorganic layer, and then a second inorganic layer may be formed on the organic layer.

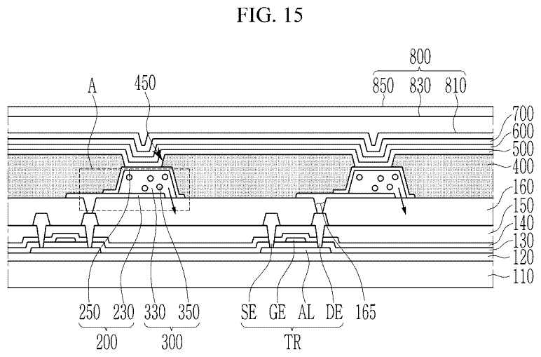

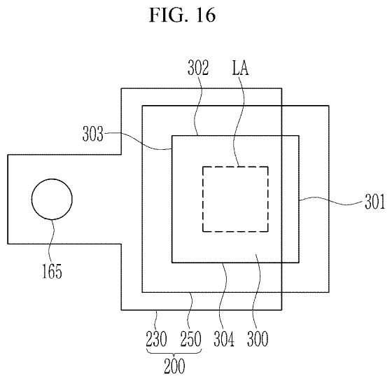

The display device according to some embodiments will now be described with reference to FIG. 15 and FIG. 16 together with FIGS. 1 to 10 described above.

FIG. 15 is a schematic cross-sectional view illustrating a portion of a display area of the display device according to some embodiments. FIG. 16 is a schematic plan view illustrating a positional relationship between the pixel electrode 200 and the scattering layer 300 of the display device according to some embodiments. FIG. 16 is a plan view schematically illustrating an area A of FIG. 15.

Here, some descriptions of contents of the present embodiments that are identical or similar to the contents of the embodiments that are described above may be omitted, and descriptions will focus on a difference between the present embodiments and the embodiments that is described above.

Referring to FIG. 15, the display device according to the present embodiments may be mostly the same as the display device according to the above-described embodiments, but a structure of a pixel electrode 200 of the display device according to the present embodiments may be different from a structure of the pixel electrode 200 of the display device according to the above-described embodiments.

Specifically, a second pixel electrode 250 according to some embodiments may overlap a portion of a first pixel electrode 230 on the first pixel electrode 230 on a plane. At least one end portion of the second pixel electrode 250 may be in contact with both the first insulating layer 160 and the second insulating layer 400. For example, the second pixel electrode 250 may be arranged to cover an upper surface and a side surface of the scattering layer 300, so that the second pixel electrode 250 is in contact with both the first insulating layer 160 and the second insulating layer 400. Here, the upper surface and the side surface of the scattering layer 300 may have the same meaning as described above. For example, the upper surface may mean a surface substantially parallel to the upper surface of the substrate 110, and the side surface may mean a surface having a constant slope with respect to the upper surface of the scattering layer 300.

The scattering layer 300 according to some embodiments may be in contact with at least a portion of the first pixel electrode 230. The first pixel electrode 230 may be in contact with the lower surface of the scattering layer 300. For example, at least a portion of the lower surface of the scattering layer 300 may be in contact with the first pixel electrode 230, and at least a portion of the lower surface of the scattering layer 300 may be in contact with the first insulating layer 160.

The scattering layer 300 may generate a gas by the photoresist resin 330 included in the scattering layer 300. If the scattering layer 300 is surrounded and sealed between the first pixel electrode 230 and the second pixel electrode 250, the gas may not be emitted to the outside of the scattering layer 300, causing damage to the pixel electrode 200, the intermediate layer 500 including the light emitting layer, and the like. However, as described above, the first pixel electrode 230 may partially expose the lower surface of the scattering layer 300 to the first insulating layer 160, so that the gas generated in the scattering layer 300 is emitted in the direction (e.g., an arrow direction of FIG. 15) of the first insulating layer 160 contacting the scattering layer 300.

The second pixel electrode 250 according to some embodiments may be in contact with the upper surface and the side surface of the scattering layer 300. For example, the second pixel electrode 250 may cover at least a portion of the upper surface and the side surface of the scattering layer 300. Therefore, the upper surface and the side surface of the scattering layer 300 may not be exposed to the outside of the second pixel electrode 250, and the upper surface and the side surface of the scattering layer 300 may not be in contact with the second insulating layer 400.

According to some embodiments, the first pixel electrode 230 may overlap the contact hole 165 of the first insulating layer 160 on a plane. The first pixel electrode 230 may overlap the contact hole 165 to be electrically connected to the transistor TR through the contact hole 165. The second pixel electrode 250 may not overlap the contact hole 165 of the first insulating layer 160 on a plane.

At least a portion of the lower surface of the scattering layer 300 according to some embodiments may overlap the first pixel electrode 230. At least a portion of the lower surface of the scattering layer 300 may not overlap the first pixel electrode 230. The second pixel electrode 250 may be arranged while covering the scattering layer 300 in its entirety. The second pixel electrode 250 may cover at least a portion of the side surface and the entire upper surface of the scattering layer 300.

According to some embodiments, the lower surface of the scattering layer 300 may be in contact with the first insulating layer 160 through a portion where the lower surface of the scattering layer 300 does not overlap the first pixel electrode 230.

At least a portion of the lower surface of the scattering layer 300 may not overlap the first pixel electrode 230, so that at least a portion of the lower surface of the scattering layer 300 may be exposed in the direction of the first insulating layer 160, and the scattering layer 300 may be in contact with the first insulating layer 160. Accordingly, the gas that may be generated in the scattering layer 300 may be emitted to the first insulating layer 160, and the gas may be isolated or sealed in the scattering layer 300 so that instances of the gas damaging the pixel electrode 200, the intermediate layer 500 including the light emitting layer, and the like, may be prevented or reduced. Therefore, dark spot defects that may be caused by the damage may be prevented or reduced, and display defects of the display device may be prevented or reduced.

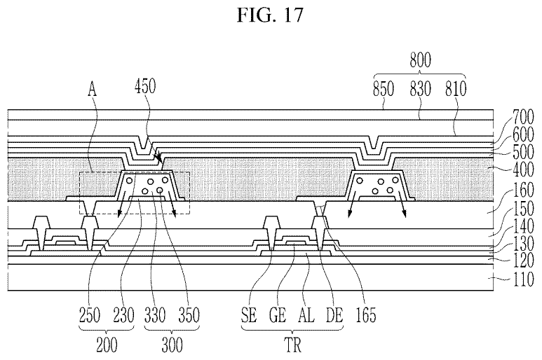

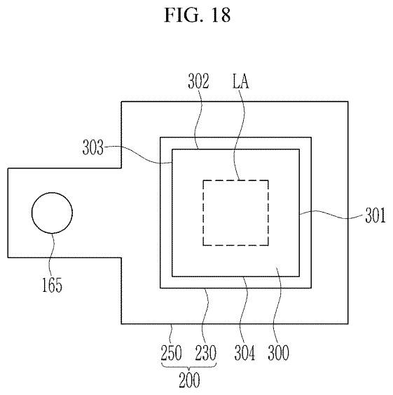

The display device according to some embodiments will now be described with reference to FIG. 17 and FIG. 18 together with FIGS. 1 to 10 described above.

FIG. 17 is a schematic cross-sectional view illustrating a portion of a display area of the display device according to some embodiments. FIG. 18 is a schematic plan view illustrating a positional relationship between the pixel electrode 200 and the scattering layer 300 of the display device according to some embodiments. FIG. 18 is a schematic plan view illustrating an area A of FIG. 17.

Here, some descriptions of features of the present embodiments that are identical to the features of the embodiments that are described above may be omitted, and differences will be emphasized.

Referring to FIG. 17, a first pixel electrode 230 according to some embodiments may not overlap the contact hole 165 of the first insulating layer 160 on a plane. A second pixel electrode 250 may overlap the contact hole 165 of the first insulating layer 160 on a plane. The second pixel electrode 250 may be electrically connected to the transistor TR through the contact hole 165 of the first insulating layer 160.

The first pixel electrode 230 may be located on the first insulating layer 160. The second pixel electrode 250 may cover the first pixel electrode 230 in its entirety. For example, the first pixel electrode 230 may overlap the second pixel electrode 250 on a plane on the first insulating layer 160 in its entirety.

The first pixel electrode 230 may be separated from the second pixel electrode 250. For example, the first pixel electrode 230 may be electrically and physically separated from the second pixel electrode 250. The first pixel electrode 230 may be covered by the scattering layer 300. The first pixel electrode 230 may be surrounded by the first insulating layer 160 and the scattering layer 300 to be isolated or sealed between the first insulating layer 160 and the scattering layer 300. Therefore, the first pixel electrode 230 may not be in contact with the second pixel electrode 250, and may be electrically and physically separated from the second pixel electrode 250. The first pixel electrode 230 may be used as a reflective layer. For example, light may be reflected in the direction of the substrate through scattering, refraction, or the like so that a path of light is changed in the direction of the common electrode or the light emitting layer. Accordingly, an amount of light in a frontal direction may be increased, and visibility may be relatively improved.

According to some embodiments, the scattering layer 300 may be located on the first pixel electrode 230 while covering the first pixel electrode 230 in its entirety. The scattering layer 300 may be located between the first pixel electrode 230 and the second pixel electrode 250 while covering the first pixel electrode 230 in its entirety. The lower surface of the scattering layer 300 may be in contact with the entire upper surface of the first pixel electrode 230, and at least a portion of the lower surface of the scattering layer 300 may be in contact with the first insulating layer 160. Here, the lower surface of the scattering layer 300 may have the same meaning as described above. For example, the lower surface may mean a surface substantially parallel to an upper surface of the substrate 110.

The scattering layer 300 may be in contact with the second pixel electrode 250. The scattering layer 300 may overlap the first pixel electrode 230 in its entirety and at least a portion of the second pixel electrode 250 on a plane.

The scattering layer 300 may generate a gas by the photoresist resin 330 included in the scattering layer 300. If the scattering layer 300 is isolated or sealed between the first pixel electrode 230 and the second pixel electrode 250, the gas may not be emitted to the outside of the scattering layer 300 causing damage to the pixel electrode 200, the intermediate layer 500 including the light emitting layer, and the like. However, as described above, the first pixel electrode 230 may partially expose the lower surface of the scattering layer 300 to the first insulating layer 160, so that the gas generated in the scattering layer 300 is emitted in the direction (e.g., an arrow direction of FIG. 17) of the first insulating layer 160 contacting the scattering layer 300.

Referring to FIG. 18, the first pixel electrode 230, the second pixel electrode 250, and the scattering layer 300 may overlap the light emitting area LA.

The second pixel electrode 250 may overlap the contact hole 165 of the first insulating layer 160 on a plane. The second pixel electrode 250 may overlap the contact hole 165 to be electrically connected to the transistor TR through the contact hole 165. The first pixel electrode 230 may not overlap the contact hole 165 of the first insulating layer 160 on a plane.

According to some embodiments, the scattering layer 300 may be located on the first pixel electrode 230 while overlapping the first pixel electrode 230 on a plane in its entirety. The lower surface of the scattering layer 300 may overlap the upper surface of the first pixel electrode 230 in its entirety. At least a portion of the lower surface of the scattering layer 300 may not overlap the first pixel electrode 230. The second pixel electrode 250 may be arranged while covering the scattering layer 300 in its entirety. The second pixel electrode 250 may cover the side surface in its entirety and the upper surface of the scattering layer 300 in its entirety. Here, the upper surface and the side surface of the scattering layer 300 may have the same meaning as described above. For example, the upper surface may mean a surface substantially parallel to the upper surface of the substrate 110, and the side surface may mean a surface having a constant slope with respect to the upper surface of the scattering layer 300.

The scattering layer 300 may be located between the first pixel electrode 230 and the second pixel electrode 250, and the lower surface of the scattering layer 300 may be in contact with the first insulating layer 160 through a portion where the lower surface of the scattering layer 300 does not overlap the first pixel electrode 230.

At least a portion of the lower surface of the scattering layer 300 may not overlap the first pixel electrode 230, so that at least a portion of the lower surface of the scattering layer 300 is exposed in the direction of the first insulating layer 160 and the scattering layer 300 is in contact with the first insulating layer 160. Accordingly, the gas that may be generated in the scattering layer 300 may be emitted to the first insulating layer 160, and the gas may be isolated in the scattering layer 300 so that instances of the gas damaging the pixel electrode 200, the light emitting layer, and the like, may be prevented or reduced. Thus, it may be possible to prevent or reduce a display defect of the display device by preventing or reducing dark spot defects that may be caused by the damage.

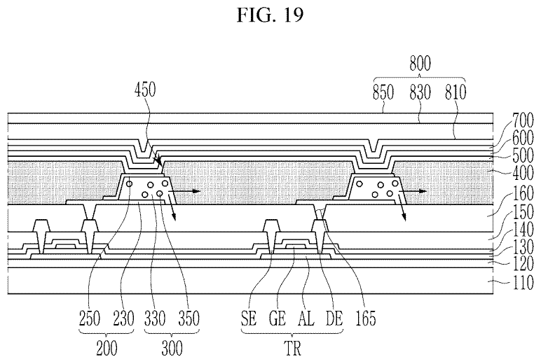

The display device according to some embodiments will now be described with reference to FIG. 19 together with the drawings described above.

FIG. 19 is a schematic cross-sectional view illustrating a portion of a display area of the display device according to some embodiments. Some escriptions of contents of the embodiments of FIG. 19 identical or similar to the contents of the embodiments described with reference to FIG. 2, FIG. 15, and FIG. 17 may be omitted.

Referring to FIG. 19, the display device according to some embodiments may be mostly the same as the display device according to the embodiments shown in FIGS. 2 to 6 described above, but may also include the feature according to the embodiments shown in FIG. 15 and FIG. 16. Specifically, the pixel electrode 200 may overlap the contact hole 165 of the first insulating layer 160 on a plane. At least one of the first pixel electrode 230 or the second pixel electrode 250 may overlap the contact hole 165 on a plane. At least one of the first pixel electrode 230 or the second pixel electrode 250 may be electrically connected to the transistor TR through the contact hole 165.

The second pixel electrode 250 may be located on the first pixel electrode 230 to at least partially overlap the first pixel electrode 230 on a plane.

The scattering layer 300 may be located on the first pixel electrode 230 while contacting the first insulating layer 160, the first pixel electrode 230, the second pixel electrode 250, and the second insulating layer 400. The scattering layer 300 may be located between the first pixel electrode 230 and the second pixel electrode 250 while contacting the first insulating layer 160, the first pixel electrode 230, the second pixel electrode 250, and the second insulating layer 400. The scattering layer 300 may overlap the first insulating layer 160, the first pixel electrode 230, the second pixel electrode 250, and the second insulating layer 400 on a plane.

The scattering layer 300 may partially contact the first pixel electrode 230. The first pixel electrode 230 may be in contact with the lower surface of the scattering layer 300. The scattering layer 300 may partially contact the second pixel electrode 250. The second pixel electrode 250 may cover at least a portion of the side surface and at least a portion of the upper surface of the scattering layer 300. For example, the scattering layer 300 may have approximately a quadrangular shape, and the second pixel electrode 250 may cover one to three of four corners or at least a portion of an edge of the scattering layer 300. Here, the upper surface, the lower surface, and the side surface of the scattering layer 300 may have the same meaning as described above. For example, the upper surface and the lower surface may mean surfaces substantially parallel to the upper surface of the substrate 110, and the side surface may mean a surface having a constant slope with respect to the upper surface of the scattering layer 300.

At least a portion of the lower surface of the scattering layer 300 may be in contact with the first pixel electrode 230, and at least a portion of the upper surface and at least a portion of the side surface of the scattering layer 300 may be in contact with the second pixel electrode 250. The scattering layer 300 may be in contact with both the first insulating layer 160 and the second insulating layer 400 through a portion where the scattering layer 300 is not in contact with the first pixel electrode 230 and the second pixel electrode 250.

According to the present embodiments, the first pixel electrode 230 may partially expose the lower surface of the scattering layer 300 to the first insulating layer 160, and the second pixel electrode 250 may partially expose the side and upper surfaces of the scattering layer 300 to the second insulating layer 400. Accordingly, a gas generated in the scattering layer 300 may be emitted in the direction (e.g., an arrow direction of FIG. 19) of the first insulating layer 160 contacting the scattering layer 300.

The second insulating layer 400 may overlap all of the first pixel electrode 230, the second pixel electrode 250, and the scattering layer 300 on a plane. For example, the second insulating layer 400 may overlap the first pixel electrode 230 on a plane without contacting the first pixel electrode 230, and may overlap the second pixel electrode 250 and the scattering layer 300 on a plane while coming in contact with the second pixel electrode 250 and the scattering layer 300.

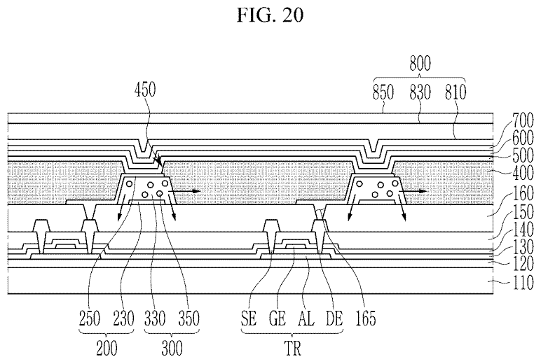

The display device according to some embodiments will now be described with reference to FIG. 20 together with the drawings described above.

FIG. 20 is a schematic cross-sectional view illustrating a portion of a display area of the display device according to some embodiments. Descriptions of contents of the embodiments of FIG. 20 that are identical or similar to the contents of the embodiments described with reference to FIG. 2, FIG. 15, FIG. 17, and FIG. 19 will be omitted.

Referring to FIG. 20, the display device according to some embodiments may be mostly the same as the display device according to the embodiments shown in FIGS. 2 to 6 described above, but may also include the feature according to the embodiments shown in FIG. 17 and FIG. 18.

Specifically, the first pixel electrode 230 may not overlap the contact hole 165 of the first insulating layer 160 on a plane. The second pixel electrode 250 may overlap the contact hole 165 of the first insulating layer 160 on a plane. The second pixel electrode 250 may be electrically connected to the transistor TR through the contact hole 165 of the first insulating layer 160.

The second pixel electrode 250 may partially cover the first pixel electrode 230. For example, the first pixel electrode 230 may be located on the first insulating layer 160 to partially overlap the second pixel electrode 250 on a plane.

The first pixel electrode 230 may be separated from the second pixel electrode 250. For example, the first pixel electrode 230 may be electrically and physically separated from the second pixel electrode 250. The first pixel electrode 230 may be covered by the scattering layer 300. The first pixel electrode 230 may be isolated or sealed between the first insulating layer 160 and the scattering layer 300. Therefore, the first pixel electrode 230 may not come into contact with the second pixel electrode 250, and may be electrically and physically separated from the second pixel electrode 250. The first pixel electrode 230 may be used as a reflective layer. For example, light may be reflected in the direction of the substrate through scattering, refraction, or the like so that a path of light is changed in the direction of the common electrode or the light emitting layer. Accordingly, an amount of light in a frontal direction may be increased, and visibility may be relatively improved.

The scattering layer 300 may be located on the first pixel electrode 230 while covering the first pixel electrode 230 in its entirety. The scattering layer 300 may be located between the first pixel electrode 230 and the second pixel electrode 250 while covering the first pixel electrode 230 in its entirety. A lower surface of the scattering layer 300 may be in contact with the entire upper surface of the first pixel electrode 230, and at least a portion of the lower surface of the scattering layer 300 may be in contact with the first insulating layer 160. Here, the lower surface of the scattering layer 300 may have the same meaning as described above. For example, the lower surface may mean a surface substantially parallel to the upper surface of the substrate 110.

The scattering layer 300 may partially contact the second pixel electrode 250. The second pixel electrode 250 may be in contact with at least a portion of the upper surface and at least a portion of the side surface of the scattering layer 300. The second pixel electrode 250 may cover at least a portion of the side surface and at least a portion of the upper surface of the scattering layer 300. For example, the scattering layer 300 may have approximately a quadrangular shape, and the second pixel electrode 250 may cover one to three of four corners of the scattering layer 300. Here, the upper surface and the side surface of the scattering layer 300 may have the same meaning as described above. For example, the upper surface may mean a surface substantially parallel to the upper surface of the substrate 110, and the side surface may mean a surface having a constant slope with respect to the upper surface of the scattering layer 300.

The lower surface of the scattering layer 300 may be in contact with the entire upper surface of the first pixel electrode 230, and at least a portion of the upper surface and at least a portion of the side surface of the scattering layer 300 may be in contact with the second pixel electrode 250. The scattering layer 300 may be in contact with both the first insulating layer 160 and the second insulating layer 400 through a portion where the scattering layer 300 is not in contact with the first pixel electrode 230 and the second pixel electrode 250.

As described above, the lower surface of the scattering layer 300 may be partially exposed to the first insulating layer 160, and the side and upper surfaces of the scattering layer 300 may be partially exposed to the second insulating layer 400.

Accordingly, a gas generated in the scattering layer 300 may be emitted in the direction (e.g., an arrow direction of FIG. 20) of the first insulating layer 160 contacting the scattering layer 300.

A display device according to some embodiments may be applied to various electronic devices. An electronic device according to some embodiments may include the display device, and may further include modules or devices having additional functions other than the display device.

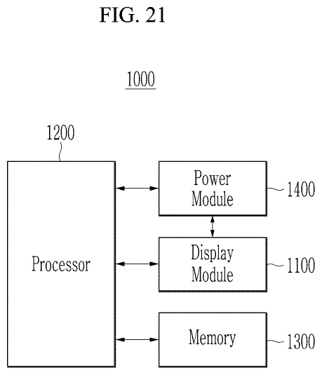

FIG. 21 is a block diagram of an electronic device according to some embodiments. Referring to FIG. 21, the electronic device 1000 according to some embodiments may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), or a controller.

The memory 1300 may store data information necessary for operations of the processor 1200 or the display module 1100. When the processor 1200 executes an application stored in the memory 1300, video data signals and/or input control signals are transmitted to the display module 1100, and the display module 1100 can process the received signals to output video information through the display screen.

The power module 1400 may include a power supply module such as a power adapter or battery device, and a power conversion module that converts the power supplied by the power supply module to generate the power necessary for the operation of the electronic device 1000.

At least one of components of the electronic device 1100 may be included within the display device according to the above-described embodiments. Additionally, some of the individual modules that are functionally included within a single module may be incorporated into the display device, while others may be provided separately from the display device. For example, the display device may include the display module 1100, while the processor 1200, memory 1300, and power module 1400 may be provided in a form of other devices within the electronic device 1100 that are not part of the display device.

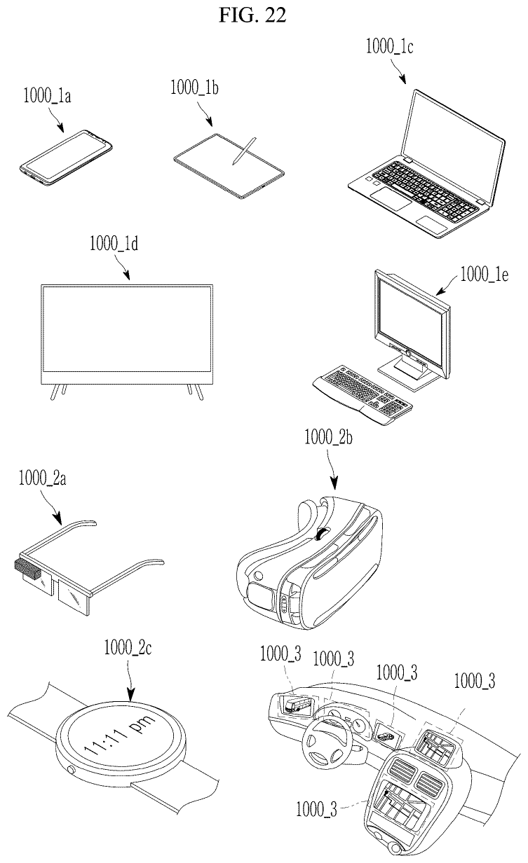

FIG. 22 shows schematic diagrams of electronic devices according to various embodiments.

Referring to FIG. 22, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

While aspects of some embodiments of the present disclosure have been described in connection with what is presently considered to be practical embodiments, it should be understood that the disclosure is not limited to the disclosed embodiments, but, on the contrary, is intended to cover various modifications and equivalent arrangements included within the spirit and scope of the appended claims, and their equivalents.

### DESCRIPTION OF SYMBOLS

110: substrate 160: first insulating layer
165: contact hole 200: pixel electrode
230: first pixel electrode 250: second pixel electrode
300: scattering layer 330: photoresist resin
350: scatterers 400: second insulating layer
600: common electrode TR: transistor

What is claimed is:

1. A display device comprising:
a substrate;
a transistor above the substrate;
a first insulating layer above the substrate;
a second insulating layer on the first insulating layer;
a first pixel electrode on the first insulating layer;
a scattering layer on the first pixel electrode and is in contact with the second insulating layer;
a second pixel electrode on the scattering layer and overlaps the first pixel electrode in a plan view;
a light emitting layer on the second pixel electrode; and
a common electrode on the light emitting layer,
wherein at least one of the first pixel electrode or the second pixel electrode is electrically connected to the transistor.

2. The display device of claim 1, wherein the first insulating layer includes a contact hole, and
the first pixel electrode overlaps the contact hole in the plan view.

3. The display device of claim 2, wherein the second pixel electrode overlaps the contact hole in the plan view.

4. The display device of claim 2, wherein the second pixel electrode does not overlap the contact hole in the plan view.

5. The display device of claim 1, wherein the second insulating layer is in contact with all of the first pixel electrode, the scattering layer, and the second pixel electrode.

6. The display device of claim 1, wherein the second pixel electrode overlaps the first pixel electrode in the plan view in its entirety.

7. The display device of claim 1, wherein the first pixel electrode includes a first transparent conductive oxide layer including transparent conductive oxide and a first metal layer including a metallic material, and
the second pixel electrode includes a second transparent conductive oxide layer including transparent conductive oxide.

8. The display device of claim 1, wherein the scattering layer includes a photoresist resin and a plurality of scatterers within the photoresist resin.

9. The display device of claim 1, wherein the scattering layer is in contact with the first insulating layer.

10. The display device of claim 9, wherein the first insulating layer includes a contact hole, and
at least one of the first pixel electrode or the second pixel electrode overlaps the contact hole.

11. The display device of claim 9, wherein the second insulating layer overlaps all of the first pixel electrode, the scattering layer, and the second pixel electrode in the plan view.

12. A display device comprising:
a substrate;
a transistor above the substrate;
a first insulating layer above the substrate and includes a contact hole;
a second insulating layer on the first insulating layer;
a first pixel electrode electrically connected to the transistor;
a scattering layer on the first pixel electrode and is in contact with the first insulating layer;
a second pixel electrode on the scattering layer and partially overlaps the first pixel electrode;
a light emitting layer on the second pixel electrode; and
a common electrode on the light emitting layer,
wherein only one of the first pixel electrode and the second pixel electrode overlaps the contact hole in a plan view, and
at least one end portion of the second pixel electrode is in contact with both the first insulating layer and the second insulating layer.

13. The display device of claim 12, wherein the second pixel electrode covers upper and side surfaces of the scattering layer in their entireties.

14. The display device of claim 12, wherein the first pixel electrode overlaps the contact hole in the plan view, and
the second pixel electrode does not overlap the contact hole in the plan view.

15. The display device of claim 12, wherein the first pixel electrode does not overlap the contact hole in the plan view, and
the second pixel electrode overlaps the contact hole in the plan view.

16. The display device of claim 15, wherein the first pixel electrode is separated from the second pixel electrode.

17. The display device of claim 16, wherein the second pixel electrode covers the first pixel electrode in its entirety.

18. The display device of claim 16, wherein the scattering layer covers the first pixel electrode in its entirety between the first pixel electrode and the second pixel electrode.

19. An electronic device, comprising:
a display device including:
a substrate;
a transistor above the substrate;
a first insulating layer above the substrate;
a second insulating layer on the first insulating layer;
a first pixel electrode on the first insulating layer;
a scattering layer on the first pixel electrode and is in contact with the second insulating layer;
a second pixel electrode on the scattering layer and overlaps the first pixel electrode in a plan view;
a light emitting layer on the second pixel electrode; and
a common electrode on the light emitting layer,
wherein at least one of the first pixel electrode or the second pixel electrode is electrically connected to the transistor.

20. The electronic device of claim 19, wherein the scattering layer is in contact with the first insulating layer.
